(19) United States
(12) Patent Application Publication
(10) Pub. No.: US 2014/0342101 A1
(43) Pub. Date: Nov. 20, 2014

(54) METHOD FOR PREPARING THE LOW TEMPERATURE POLY-SILICON FILM

(71) Applicant: EverDisplay Optronics (Shanghai) Limited, Shanghai (CN)

(72) Inventors: SsuChun Peng, Shanghai (CN); ChienHung Wu, Shanghai (CN); Chong Liu, Shanghai (CN); XiaoLong Yan, Shanghai (CN)

(73) Assignee: EverDisplay Optronics (Shanghai) Limited, Shanghai (CN)

(21) Appl. No.: 14/278,755

(22) Filed: May 15, 2014

(30) Foreign Application Priority Data
May 16, 2013 (CN) 201310182928.1

(51) Int. Cl. C23C 16/40; C23C 16/56

(52) U.S. Cl. CPC C23C 16/401; C23C 16/56
USPC 427/554

(57) ABSTRACT

A method for preparing the low temperature ploy-silicon film, which includes the following steps: providing a substrate; forming an amorphous silicon layer on the substrate; forming a silicon oxide layer on the amorphous silicon layer by a plasma process; and performing a laser crystallizing process to the amorphous silicon layer. An embodiment of the present invention prepares the silicon oxide film in the low temperature ploy-silicon film by the plasma enhanced chemical vapor deposition process, which improves the overall uniformity of the silicon oxide film and owns a preferred roughness surface.

### CROSS-REFERENCE TO RELATED APPLICATIONS

The present application claims priority to and the benefit of Chinese Patent Application No. CN201310182928.1, filed on May 16, 2013, the entire content of which is incorporated herein by reference.

### BACKGROUND OF THE INVENTION

1. Field of the Invention

The present invention relates to a method for preparing the optoelectronic device, more specifically, to a method for preparing the low temperature poly-silicon film.

2. Description of the Related Art

Low Temperature Poly-Silicon (“LPTS”, hereinafter) is a branch of the poly-silicon technology. Currently, the aim of the development of the display technology is to produce the devices which are thinner and smaller. The poly-silicon material has many advantages for the LCD devices, such as the thinner, smaller and lower energy cost film circuit can be produced thereby. However, the poly-silicon need to be annealed during the manufacturing in order to transformed the amorphous silicon structure into the poly-silicon structure. And in the conventional annealing process, the temperature will be above 1000° C., so that the glass substrate will be soften and melted in the temperature of 1000° C. which results the substrate become unable to use. Therefore, the low temperature poly-silicon technology arises at the moment.

In the annealing process of the low temperature poly-silicon process, the excimer laser is used as the heat source. The excimer laser generates an energy evenly distributed laser beam and is projected to the glass substrate of the amorphous silicon structure after the excimer laser goes through the transmission system. When the glass substrate of the amorphous silicon structure absorbs the excimer laser energy, it will be transformed into the poly-silicon structure. The temperature in the whole process is under 600° C., which enables the low temperature poly-silicon technology to be applied to the mass production in industry.

A related art disclosed a method for preparing the low temperature poly-silicon film. The steps shown in FIG. 1 including: Firstly, 101: preparing a buffer layer on the surface of the glass substrate, the buffer layer covers the glass substrate; 102: preparing an amorphous silicon layer on the buffer layer, which it covers the upper surface of the buffer layer. The surface of the amorphous silicon is very easily to form an original oxide layer. Therefore, the original oxide needs to be removed. Secondly, 103: removing the original oxide layer located on the amorphous silicon layer by the hydrofluoric acid. Afterwards, 104: adopting the ozone water to oxidize the surface of the amorphous silicon and thus to form a silicon oxide film. Ultimately, 105: performing the laser crystallizing technology. In the current process of preparing the low temperature poly-silicon film, due to the use of the two steps of wet operation with the hydrofluoric acid and the ozone water. Consequently, the metal impurities may be introduced into in the process. And when the ozone water is used to oxidize the surface of the amorphous silicon, it is not easy to control the thickness and uniformity of the oxide layer surface.

Another related art disclosed a method of manufacturing a film transistor, including: forming an amorphous silicon on a substrate; forming a cover layer which comprises a metal catalyst with different concentrations in accordance with the thickness of the amorphous silicon layer; patterning the cover layer; and crystallizing the amorphous silicon layer in order to control the density and location of the seed formed between amorphous silicon layer and cover layer and to improve the size and uniformity of the particle, and a crystallization process further comprises that select forming a poly-silicon of required size and uniformity in the required position. Although the related art has disclosed a poly-silicon film transistor, it did not mention the improved technical solution for the above problems.

Another related art disclosed a method of excimer laser recrystallization process, including: providing a substrate, the surface of the substrate is defined with a first region and a second region; forming an amorphous silicon film on the substrate; forming a mask layer at the top of the amorphous silicon film; removing the mask layer on the first region; forming a hot covered layer which is covered on the mask layer and the amorphous silicon film; and finally performing the excimer laser recrystallization process so that the amorphous silicon film of the first region can recrystallize into the ploy-silicon film. However, the related art only disclosed a process of recrystallizing the low temperature excimer laser without solving the above problems in the related art. Consequently, the effective solutions for the above problems have not been concluded.

### SUMMARY OF THE INVENTION

An embodiment of the present disclosure is directed toward a method for preparing the low temperature poly-silicon film, which is capable of stabilizing the lower temperature poly-silicon film by providing the evenly distributed silicon oxide as well as the preferred roughness on the surface and preventing the metal pollution during the preparing process.

The method for preparing the low temperature poly-silicon film, comprising:
(a) providing a substrate;
(b) forming an amorphous silicon layer on the substrate;
(c) forming a silicon oxide layer on the amorphous silicon layer by a plasma process; and
(d) performing a laser crystallizing process to the amorphous silicon layer.

According to one embodiment of the present disclosure, wherein the substrate comprises a base substrate and a buffer layer; an upper surface of the base substrate is covered with the buffer layer, and an upper surface of the buffer layer is covered with the amorphous silicon layer.

According to one embodiment of the present disclosure, wherein the thickness of the silicon oxide layer is 10 Å to 100 Å.

According to one embodiment of the present disclosure, wherein the plasma process comprises plasma enhanced chemical vapor deposition process.

According to one embodiment of the present disclosure, wherein the plasma enhanced chemical vapor deposition process is adopted for forming the amorphous silicon layer.

According to one embodiment of the present disclosure, wherein material of the base substrate is glass.

According to one embodiment of the present disclosure, wherein the plasma process comprises that an oxygen containing plasma is used to oxidize the amorphous silicon layer for preparing the silicon oxide layer.

According to one embodiment of the present disclosure, wherein the oxygen containing plasma comprises plasma consisting of N₂O and/or NO and/or O₂.

According to one embodiment of the present disclosure, wherein the plasma process comprises the interaction of the oxygen containing plasma and a silicon containing plasma, so that the silicon oxide layer can be deposited on the upper surface of the amorphous silicon layer.

According to one embodiment of the present disclosure, wherein the oxygen containing plasma comprises plasma consisting of N₂O and/or NO and/or O₂.

According to one embodiment of the present disclosure, wherein the silicon containing plasma comprises plasma consisting of SiH₄ and/or TEOS.

### BRIEF DESCRIPTIONS OF THE DRAWINGS

The accompanying drawings, together with the specification, illustrate exemplary embodiments of the present disclosure, and, together with the description, serve to explain the principles of the present disclosure.

FIG. 1 shows a schematic diagram of the method for preparing the low temperature poly-silicon film in the related art;

FIG. 2 shows a schematic diagram of the method for preparing the low temperature poly-silicon film in an embodiment of the present disclosure;

FIG. 3A shows a schematic diagram of the environment for preparing the silicon oxide layer in Embodiment 1 of the present disclosure;

FIG. 3B shows a schematic diagram of the environment for preparing the silicon oxide layer in Embodiment 2 of the present disclosure.

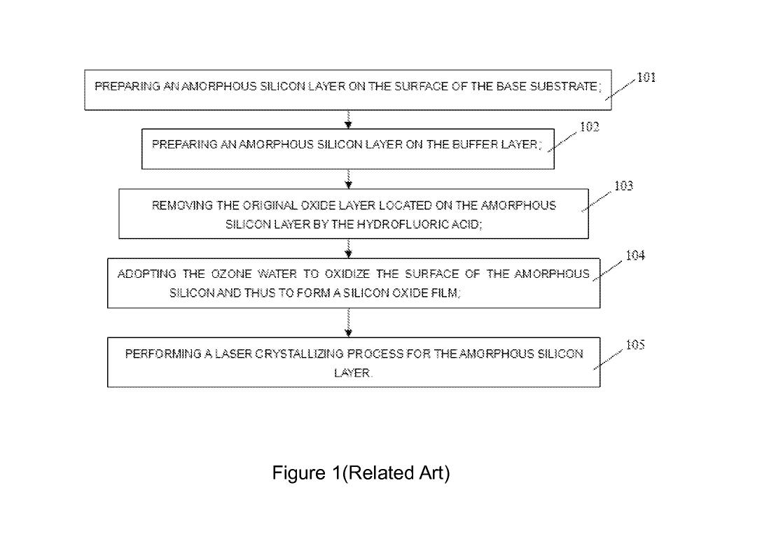

### DETAILED DESCRIPTIONS

The present invention will now be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

As used herein, the term “plurality” means a number greater than one.

Hereinafter, certain exemplary embodiments according to the present disclosure will be described with reference to the accompanying drawings.

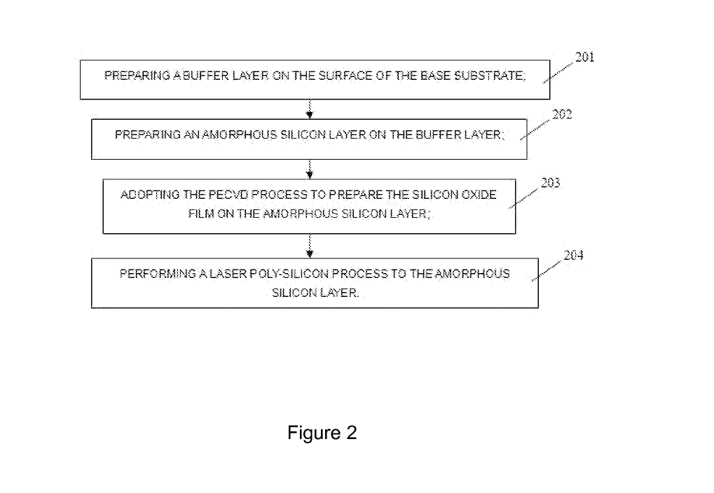

FIG. 2 shows a schematic diagram of the method for preparing the low temperature poly-silicon film in an embodiment of the present disclosure. As shown in FIG. 2, the method for preparing the low temperature poly-silicon film comprises the following steps:

201, preparing a buffer layer on a base substrate, and the buffer layer covers the upper surface of the base substrate. The substrate in this embodiment consists of the base substrate and the buffer layer. In this step, the substrate is made of glass or quartz, which is well known in the art. Preferably, the substrate should be a glass substrate in the industrial mass production due to the consideration of the cost. In addition, the buffer layer can be a SiO₂ buffer layer, or the composite buffer layer of SiNx and SiO₂. The effect of the buffer layer is to prevent the impurities in the substrate from diffusing into the upper structure in the subsequent process, which affects the performance of the low temperature ploy-silicon film.

202, preparing an amorphous silicon layer on the buffer layer through Plasma Enhanced Chemical Vapor Deposition (“PECVD”, hereinafter).

203, adopting Plasma Enhanced Chemical Vapor Deposition to prepare a silicon oxide film covering the upper surface of the amorphous silicon layer. The thickness of the silicon oxide layer is 10 Å to 100 Å, such as 10 Å, 20 Å, 50 Å, 65 Å, and 100 Å. The thickness in the range of 10 Å to 100 Å is feasible. And the thickness of the silicon oxide layer can be determined according to the actual condition, thus the other examples will not be listed herein.

204, performing a laser annealing process to the amorphous silicon layer. During the excimer laser annealing process and under the projection of the laser beam with the evenly distributed energy, the amorphous silicon layer absorbs the energy of the excimer laser beam so as to transform into the poly-silicon structure and thus to form the low temperature poly-silicon film. In this step, the excimer laser annealing process is performed by the excimer laser annealing equipment. As the excimer laser is well known in the art, it will not be described herein.

The method of preparing the low temperature poly-silicon film will be further illustrated based on the following embodiments.

### Embodiment 1

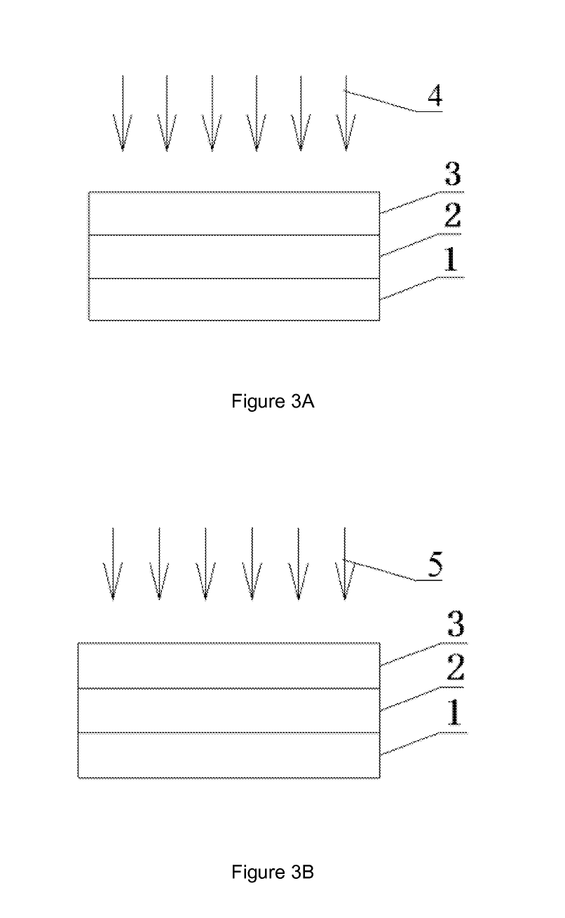

FIG. 3A shows a schematic diagram of the environment for preparing the silicon oxide layer in Embodiment 1 of the present disclosure.

As shown in FIG. 3A, a Buffer Layer 2 is formed on Glass Substrate 1, and Buffer Layer 2 covers the upper surface of Glass Substrate 1. The substrate consists of Glass Substrate 1 and Buffer Layer 2 herein. Afterwards, the plasma enhanced chemical vapor deposition process is adopted to form an Amorphous Silicon Layer 3 on the surface of Buffer Layer 2, and the Amorphous Silicon Layer 3 covers the upper surface of Buffer Layer 2. Next, the upper surface of Buffer Layer 2 is processed by Oxygen Containing Plasma 4; specifically, Plasma Enhanced Chemical Vapor Deposition is adopted to ionize the gas to affect the surface of Amorphous Silicon Layer 3. Accordingly, the oxidation effect is generated on the surface of the Amorphous Silicon Layer 3 to form a silicon oxide layer (not shown). The time of the plasma gas taking effect into the surface of Amorphous Silicon Layer 3 is controlled to form the thickness of the silicon oxide layer in the range from 10 Å to 100 Å, such as 10 Å, 20 Å, 50 Å, 65 Å and 100 Å. While the thickness meets the process requirements, the excimer laser annealing equipment is adopted to perform the laser annealing process to Amorphous Silicon Layer 3, so that Amorphous Silicon Layer 3 is transformed into the poly-silicon layer (not shown) under the excimer laser affect.

The oxygen containing gas may consist of any one or the combinations of N₂O, NO and O₂, or other gases which consist of oxygen.

### Embodiment 2

In this embodiment, the method for preparing the low temperature poly-silicon film differs from the method in Embodiment 1.

FIG. 3B shows a schematic diagram of the environment for preparing the silicon oxide layer in Embodiment 2 of the present disclosure.

The method for preparing the low temperature poly-silicon film in this embodiment will be described in detail as follows.

As shown in FIG. 3B, a Buffer Layer 2 is formed on Glass Substrate 1, and Buffer Layer 2 covers the upper surface of Glass Substrate 1 herein. The substrate consists of Glass Substrate 1 and Buffer Layer 2. Afterwards, The PECVD process is adopted to form an Amorphous Silicon Layer 3 on the surface of Buffer Layer 2, and Amorphous Silicon Layer 3 covers the surface of Buffer Layer 2. The surface of Buffer Layer 2 is processed with Oxygen Containing Plasma and Silicon Containing Plasma 5. The PECVD process is used to ionize the oxygen containing gas and the silicon containing gas on the surface of Amorphous Silicon Layer 3. The plasma consisting of the oxygen and the silicon takes effect on the surface of Amorphous Silicon Layer 3 so as to form a silicon oxide layer (not shown). The time of the plasma gas taking effect into the surface of Amorphous Silicon Layer 3 is controlled to form the thickness of the silicon oxide layer in the range from 10 Å to 100 Å, such as 10 Å, 20 Å, 50 Å, 65 Å and 100 Å. While the thickness meets the process requirements, the excimer laser tempering equipment is adopted to perform the laser annealing process to Amorphous Silicon Layer 3, so that Amorphous Silicon Layer 3 is transformed into the poly-silicon layer (not shown) under the excimer laser affect.

The silicon containing gas in the above process can be any one or the combinations of SiH₄, Tetrethy-Ortho-Silicate (TEOS), or other gases which consist of silicon. The oxygen containing gas can be any one or the combinations of N₂O, NO, O₂, or other gases which consist of oxygen. In the embodiment, the silicon containing plasma and the oxygen containing gas plasma are acted on the surface of Amorphous Silicon Layer 3. And it can be compound with any one of the above mentioned silicon compounds and oxygen containing gas so as to form the plasma gas that acts on Amorphous Silicon Layer 3.

In conclusion, in the conventional method for preparing the low temperature Poly-Silicon film, the silicon oxide layer prepared by ozone water has the poor control ability in the uniformity of the silicon oxide layer generally. Thus, the above-mentioned method is improved in accordance with the method for preparing the silicon oxide lager in the low temperature poly-silicon film. The silicon oxide layer is prepared by the plasma enhanced chemical vapor deposition instead of the ozone water so that the thickness of silicon oxide layer is more evenly distributed with preferred roughness. And the metal pollutants are effectively reduced so as to improve the stability of the low temperature poly-silicon film.

While the present disclosure has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. A method for preparing a low temperature poly-silicon film, comprising:
(a) providing a substrate;
(b) forming an amorphous silicon layer on the substrate;
(c) forming a silicon oxide layer on the amorphous silicon layer by a plasma process; and
(d) performing a laser crystallizing process to the amorphous silicon layer.

2. The method as claimed in claim 1, wherein the substrate comprises a base substrate and a buffer layer; an upper surface of the base substrate is covered with the buffer layer, and an upper surface of the buffer layer is covered with the amorphous silicon layer.

3. The method as claimed in claim 1, wherein the thickness of the silicon oxide layer is 10 Å to 100 Å.

4. The method as claimed in claim 1, wherein the plasma process comprises plasma enhanced chemical vapor deposition process.

5. The method as claimed in claim 4, wherein the plasma enhanced chemical vapor deposition process is adopted for forming the amorphous silicon layer.

6. The method as claimed in claim 2, wherein material of the base substrate is glass.

7. The method as claimed in claim 1, wherein the plasma process comprises that an oxygen containing plasma is used to oxidize the amorphous silicon layer for preparing the silicon oxide layer.

8. The method as claimed in claim 7, wherein the oxygen containing plasma comprises plasma consisting of N₂O and/or NO and/or O₂.

9. The method as claimed in claim 1, wherein the plasma process comprises the interaction of the oxygen containing plasma and a silicon containing plasma, so that the silicon oxide layer can be deposited on the upper surface of the amorphous silicon layer.

10. The method as claimed in claim 9, wherein the oxygen containing plasma comprises plasma consisting of N₂O and/or NO and/or O₂.

11. The method as claimed in claim 19, wherein the silicon containing plasma comprises plasma consisting of SiH₄ and/or TEOS.
